(19) United States
(12) Patent Application Publication
(10) Pub. No.: US 2026/0314344 A1
(43) Pub. Date: Oct. 8, 2026

(54) SUBSTRATE PRODUCTION METHOD AND CHIP PRODUCTION METHOD

(71) Applicant: DISCO CORPORATION, Tokyo (JP)

(72) Inventor: Nobuki Kakiuchi, Tokyo (JP)

(21) Appl. No.: 19/638,442

(22) Filed: Apr. 3, 2026

(30) Foreign Application Priority Data
Apr. 7, 2025 (JP) 2025-063181

(51) Int. Cl. H10P 90/00; B23K 26/53; B28D 5/00; H10P 58/00; H10P 74/20

(52) U.S. Cl. CPC H10P 90/123; B23K 26/53; B28D 5/0011; H10P 58/00; H10P 74/203

(57) ABSTRACT

A substrate production method for producing, from a workpiece, a substrate thinner than the workpiece, includes: forming a separation layer inside the workpiece by applying a laser beam having a wavelength that transmits through the workpiece from a front surface of the workpiece, positioning a focal point of the laser beam at a position deeper than the front surface of the workpiece, and relatively feeding the workpiece and the focal point; separating the substrate from the workpiece along the separation layer; acquiring warpage shape information, which is shape information of warpage of the substrate; and grinding a separated surface of the workpiece by a grinding wheel, and in the grinding, the separated surface of the workpiece exposed after separation of the substrate is ground based on the acquired warpage shape information.

### CROSS-REFERENCE TO RELATED APPLICATIONS

This application is based on and claims priority under 35 USC 119 from Japanese Patent Application No. 2025-063181 filed on Apr.7, 2025, the contents of which are incorporated herein by reference.

### TECHNICAL FIELD

The present disclosure relates to a substrate production method and a chip production method.

### BACKGROUND ART

As a method for producing a substrate such as a semiconductor, Patent Literature 1 discloses a method in which a laser beam having a transmission wavelength is focused and applied from a front surface side of a semiconductor material (SiC) ingot to form a separation layer inside the ingot, and then a plate-shaped object is separated from the ingot to generate a substrate.

Patent Literature 1: JP2016-111143A

### SUMMARY

However, since the processing state of front and back surfaces of the substrate differs after separation, warpage occurs in the substrate due to the Twyman effect. In addition, even in a substrate whose separated surface is ground and/or polished, warpage may remain due to the crystalline state. When warpage occurs in the substrate, there are problems that the substrate cannot be suctioned during transport or that the quality of the substrate may be deteriorated.

The present disclosure provides a substrate production method and a chip production method capable of reducing warpage of a substrate separated from a workpiece.

The present disclosure provides a substrate production method for producing, from a workpiece, a substrate thinner than the workpiece, the method including:
a separation layer forming step of forming a separation layer inside the workpiece by applying a laser beam having a wavelength that transmits through the workpiece from a front surface of the workpiece, positioning a focal point of the laser beam at a position deeper than the front surface of the workpiece, and relatively feeding the workpiece and the focal point;
a separation step of separating the substrate from the workpiece along the separation layer;
a warpage shape information acquisition step of acquiring warpage shape information, which is shape information of warpage of the substrate; and
a workpiece grinding step of grinding a separated surface of the workpiece by a grinding wheel, in which in the workpiece grinding step, the separated surface of the workpiece exposed after separation of the substrate is ground based on the warpage shape information acquired in the warpage shape information acquisition step.

The present disclosure also provides a chip production method including:
a substrate production step of producing a substrate by the substrate production method described above;
a front-end step of producing a plurality of semiconductor devices on the substrate; and
a back-end step of producing a semiconductor chip by cutting the substrate on which the plurality of semiconductor devices are formed.

### BRIEF DESCRIPTION OF DRAWINGS

FIG. 1 is a perspective view illustrating a laser processing apparatus 1.

FIG. 2 is a diagram illustrating a laser beam applying mechanism 8.

FIG. 3 is a flowchart of an embodiment of a method for producing a substrate W.

FIG. 4 is a diagram illustrating a front surface shape information acquisition step S11.

FIG. 5 is a diagram illustrating a separation layer forming step S12.

FIG. 6 is a diagram illustrating an ingot 11 whose front surface 11a is convex at the center.

FIG. 7 is a diagram illustrating an ingot 11 whose front surface 11a is concave at the center.

FIG. 8 is a diagram illustrating a state in which ultrasonic waves are applied to the ingot 11 in a separation step S13.

FIG. 9 is a diagram illustrating a state in which a substrate W is separated from the ingot 11 in the separation step S13.

FIG. 10 is a diagram illustrating a warpage shape information acquisition step S14.

FIG. 11 is a diagram illustrating a substrate grinding step S16 of a substrate planarization step S15.

FIG. 12 is a diagram illustrating a substrate polishing step S17 of the substrate planarization step S15.

FIG. 13 is a diagram illustrating an ingot grinding step S19.

FIG. 14 is a flowchart of a modification of the method for producing a substrate W.

FIG. 15 is a flowchart of an embodiment of a chip production method.

FIG. 16 is a diagram illustrating the substrate W produced in a substrate production step S21.

FIG. 17 is a diagram illustrating a substrate W on which a plurality of semiconductor devices are formed.

### DESCRIPTION OF EMBODIMENTS

Hereinafter, an embodiment of a substrate production method of the present disclosure will be described with reference to the accompanying drawings

First, a laser processing apparatus 1 used in the substrate production method will be described.

### Laser Processing Apparatus

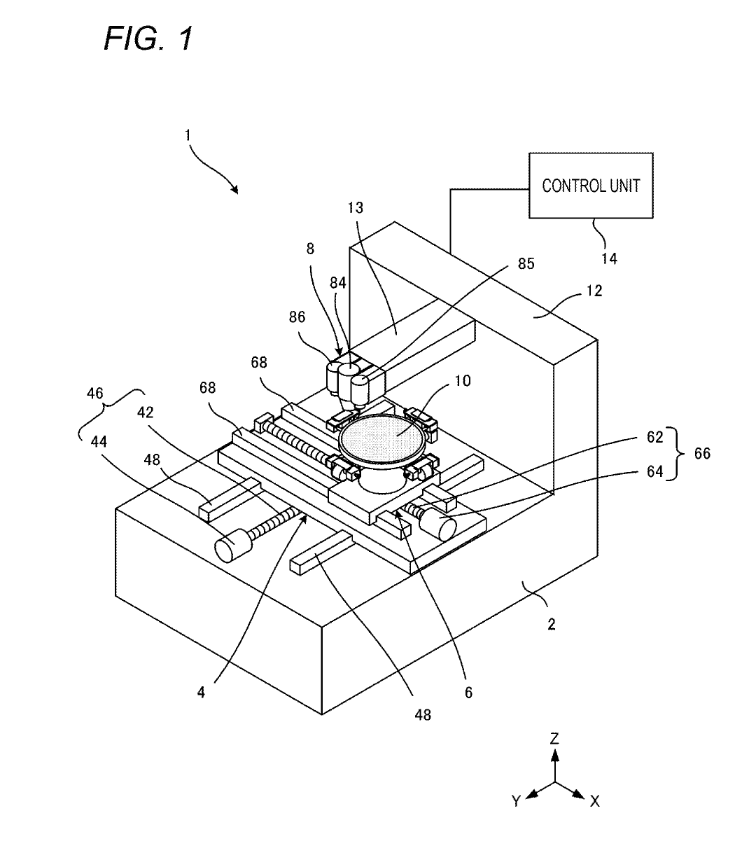

FIG. 1 is a perspective view illustrating the laser processing apparatus 1. In the following description, an X-axis direction is a direction on a horizontal plane. A Y-axis direction is a direction orthogonal to the X-axis direction on the horizontal plane. A Z-axis direction is a direction orthogonal to the X-axis direction and the Y-axis direction.

The laser processing apparatus 1 of the present embodiment includes a base 2, a first slide block 4 mounted on the base 2 so as to be movable in the Y-axis direction, a second slide block 6 mounted above the first slide block 4 and movable in the X-axis direction, a holding table 10 provided on the second slide block 6, a column 12 erected on the base 2, a laser beam applying mechanism 8 attached to the column 12, and a control unit 14 that controls the laser processing apparatus 1.

The first slide block 4 is movable in an indexing direction, that is, the Y-axis direction along a pair of guide rails 48 by an indexing mechanism 46 including a ball screw 42 and a pulse motor 44.

The second slide block 6 is mounted above the first slide block 4 so as to be movable in the X-axis direction. That is, the second slide block 6 is movable in a feeding direction, that is, the X-axis direction along a pair of guide rails 68 by a feeding mechanism 66 including a ball screw 62 and a pulse motor 64.

The holding table 10 is mounted on the second slide block 6. The holding table 10 is movable in the X-axis direction and the Y-axis direction by the feeding mechanism 66 and the indexing mechanism 46, and is rotatable by a motor accommodated in the second slide block 6.

The column 12 is erected on the base 2, and the laser beam applying mechanism 8 is attached to the column 12.

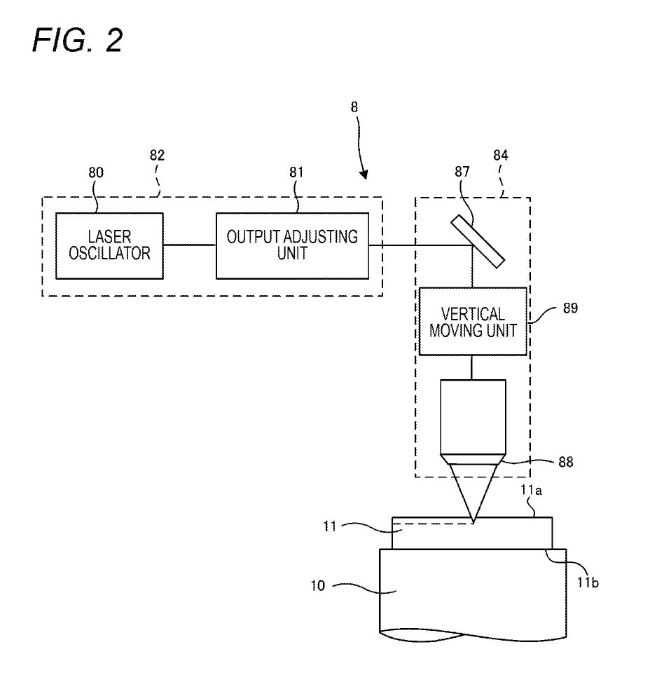

FIG. 2 is a diagram illustrating the laser beam applying mechanism 8. As illustrated in FIGS. 1 and 2, the laser beam applying mechanism 8 includes a laser beam generating unit 82 accommodated in a casing 13 and a focusing means (laser head) 84 attached to a tip end of the casing 13. An imaging unit 86 having a microscope and a camera, and a front surface shape measurement unit 85 are attached adjacent to the focusing means 84 at the tip end of the casing 13.

The laser beam generating unit 82 includes a laser oscillator 80 that oscillates a YAG laser or a YVO4 laser, and an output adjusting unit 81. Although not particularly illustrated, the laser oscillator 80 has a Brewster window, and the laser beam emitted from the laser oscillator 80 is a linearly polarized laser beam.

The output adjusting unit 81 adjusts the output of the laser beam to a predetermined power. The laser beam whose output is adjusted is reflected by a mirror 87 of the focusing means 84, and then applied to an ingot 11 (an example of a workpiece) fixed to the holding table 10 at a focal point positioned inside the ingot 11 by a focusing lens 88.

The ingot 11 is made of a semiconductor material, and is, for example, an ingot made of silicon carbide (SiC), gallium nitride, gallium oxide, or silicon nitride. The ingot 11 is not limited to a single crystal ingot and may be a polycrystalline ingot. The ingot 11 has a front surface 11a and a back surface 11b opposite to the front surface 11a. The front surface 11a of the ingot 11 is polished into a mirror finish as the front surface 11a is the surface to be applied with the laser beam.

The focusing means 84 is provided with a vertical moving unit 89, which allows the position of the focusing lens 88 to be moved in the Z-axis direction. Therefore, by moving the position of the focusing lens 88 upward by the vertical moving unit 89, the focal point inside the ingot 11 can be moved toward the front surface 11a, and by moving the position of the focusing lens 88 downward, the focal point inside the ingot 11 can be moved toward the back surface 11b.

The front surface shape measurement unit 85 can detect a front surface shape of the ingot 11 by applying distance-measuring light to the front surface 11a of the ingot 11 and detecting the reflected light of the distance-measuring light reflected by the front surface 11a of the ingot 11 so as to detect the displacement (height, position in the Z-axis direction) of the front surface 11a of the ingot 11. The distance measurement method using the front surface shape measurement unit 85 is not particularly limited, and for example, a triangulation method, a laser confocal method, a white light confocal method, a spectral interference method, an astigmatism method, or the like can be used. The measurement position is preferably coaxial with the focusing lens 88. Contact measurement using a measurement probe may also be used.

The control unit 14 controls each of the above components of the laser processing apparatus 1 to execute various processes on the workpiece. The control unit 14 is a computer including a controller that performs various calculations, a storage unit having a storage medium, and an input and output interface (not illustrated) that controls input and output of data between the inside and outside of the control unit 14. The controller includes, for example, a processor such as a central processing unit (CPU). The storage unit includes a memory such as a hard disk drive (HDD), a read only memory (ROM), or a random access memory (RAM). The controller performs various calculations based on predetermined programs stored in the storage unit. The controller outputs, according to calculation results, various control signals to the above components via the input and output interface, and controls each of the components of the laser processing apparatus 1.

The laser processing apparatus 1 forms a separation layer including a plurality of modified regions and cracks extending from the modified regions inside the ingot 11. When forming a separation layer, the laser processing apparatus 1 sets a focal point of a laser beam having a wavelength that transmits through the ingot 11 held by the holding table 10 at a position deeper than the front surface 11a of the ingot 11, and forms modified regions and cracks by focusing and applying the laser beam from the front surface 11a of the ingot 11.

### Substrate Production Method

Next, the embodiment of the substrate production method of the present disclosure will be described.

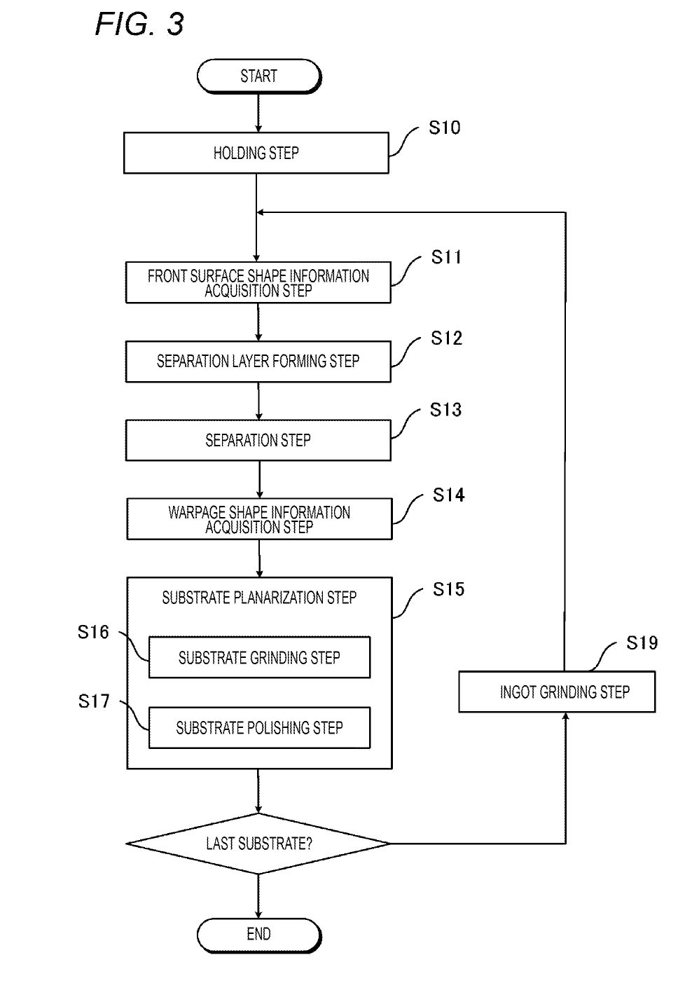

FIG. 3 is a flowchart of an embodiment of a method for producing a substrate W. The method for producing a substrate W includes a holding step S10 of holding the back surface 11b of the ingot 11 on the holding table 10, a front surface shape information acquisition step S11 of acquiring front surface shape information by measuring a front surface shape of the front surface 11a of the ingot 11, a separation layer forming step S12 of forming a separation layer by applying a laser beam to the ingot 11, a separation step S13 of separating a plate-shaped object as the substrate W from the ingot 11 starting from the separation layer, a warpage shape information acquisition step S14 of acquiring warpage shape information of the substrate W separated from the ingot 11, a substrate planarization step S15 of planarizing the substrate W separated from the ingot 11, and an ingot grinding step S19 of grinding a separated surface of the ingot 11 after the substrate W is separated, based on the warpage shape information. The holding step S10, the front surface shape information acquisition step S11, and the separation layer forming step S12 can each be performed using the laser processing apparatus 1 described above, and the processing can be executed by the control unit 14.

In the method for producing a substrate W of the present embodiment, a plurality of substrates W are generated from one ingot 11 held in the holding step S10, the front surface shape information acquisition step S11, the separation layer forming step S12, the separation step S13, the warpage shape information acquisition step S14, the substrate planarization step S15, and the substrate grinding step S16 are repeated until the last one substrate W is generated, and the processing is ended when the last one substrate W is generated. The front surface shape information acquisition step S11 and the warpage shape information acquisition step S14 do not necessarily have to be performed for each substrate W every time, and may be performed for every predetermined number of substrates W, or the number of times these steps are performed may be determined for each ingot 11.

### Holding Step

In the holding step S10, the back surface 11b of the ingot 11 is held by the holding table 10 of the laser processing apparatus 1. The holding table 10 holds the ingot 11 under suction by, for example, a suction force generated by a suction source (not illustrated).

### Shape Information Acquisition Step

The front surface 11a of the ingot 11 is ground in the ingot grinding step S19 to be described later. The front surface 11a may not be a flat surface and may be convex at the center in which an ingot central portion is thick and an outer peripheral portion is thin, or may be concave at the center in which the central portion is thin and the outer peripheral portion is thick. When a laser beam is applied from the front surface 11a of the ingot 11 that is not a flat surface and the focal point is positioned at a predetermined position deeper than the front surface 11a, the position of the focal point fluctuates. Therefore, the height of the focal point of the laser beam is preferably adjusted in accordance with the front surface shape of the ingot 11.

In order to prevent the fluctuation of the focal point, in the front surface shape information acquisition step S11, the front surface shape measurement unit 85 first applies distance-measuring light to the front surface 11a of the ingot 11 to detect the front surface shape of the entire front surface of the ingot 11.

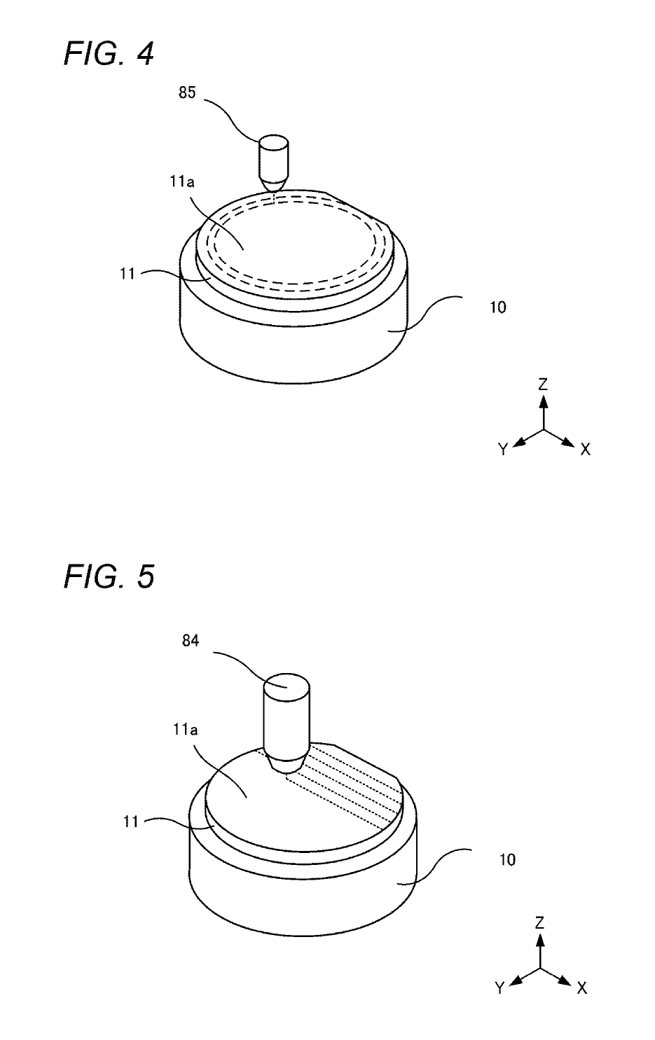

FIG. 4 is a diagram illustrating the front surface shape information acquisition step S11.

As illustrated in FIG. 4, when the front surface shape measurement unit 85 applies distance-measuring light to detect the front surface shape of the entire front surface of the ingot 11, the holding table 10 is rotated such that the distance-measuring light moves spirally from an outer edge toward the center along the outer edge of the ingot 11 or moves spirally from the center toward the outer edge. Alternatively, the front surface shape of the entire front surface of the ingot 11 may be detected by repeatedly performing a process in which the ingot 11 is fed such that the distance-measuring light moves from one end to the other end of the ingot 11 along the X-axis direction, then the ingot 11 is moved by a predetermined amount in the Y-axis direction, and then the ingot 11 is fed such that the distance-measuring light moves from the other end to the one end of the ingot 11 along the X-axis direction. By performing the front surface shape information acquisition step S11 in this manner, the front surface shape information of the front surface 11a of the ingot 11 can be acquired.

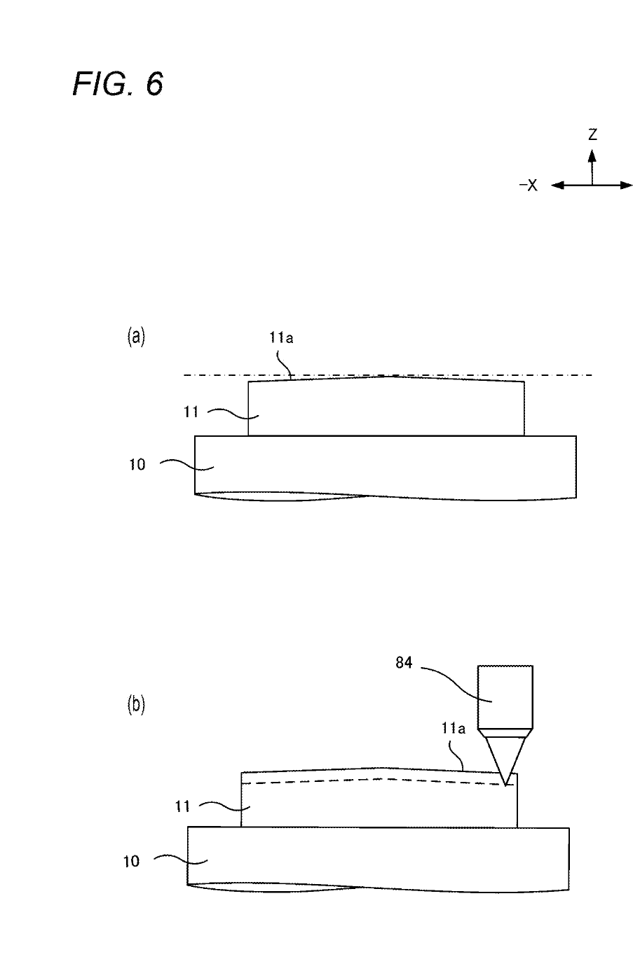

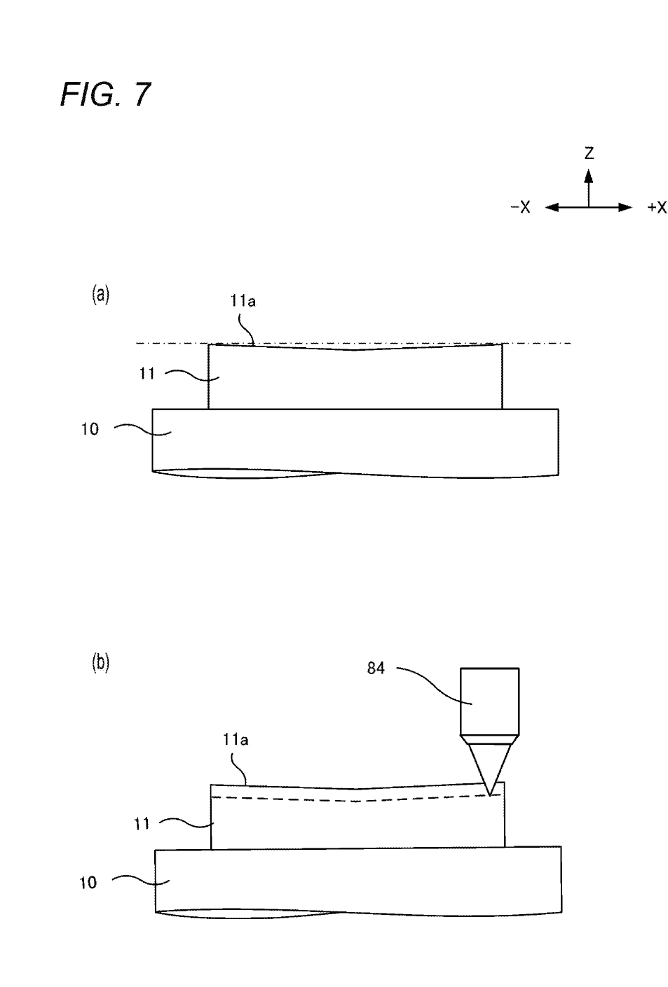

FIG. 6 is a diagram illustrating an ingot 11 whose front surface 11a is convex at the center, and FIG. 7 is a diagram illustrating an ingot 11 whose front surface 11a is concave at the center. In FIGS. 6 and 7, as illustrated in the drawings, one end (left end) in the X-axis direction is defined as a negative X-axis direction, and the other end (right end) in the X-axis direction is defined as a positive X-axis direction. The dashed line in the drawing is a horizontal line.

As illustrated in (a) of FIG. 6, in the ingot 11 whose front surface 11a is convex at the center, the height of the front surface 11a gradually increases from the negative X-axis direction toward the center, and gradually decreases toward the positive X-axis direction with the center as the highest point.

As illustrated in (a) of FIG. 7, in the ingot 11 whose front surface 11a is concave at the center, the height of the front surface 11a gradually decreases from the negative X-axis direction toward the center, and gradually increases toward the positive X-axis direction with the center as the lowest point.

### Separation Layer Forming Step

FIG. 5 is a diagram illustrating the separation layer forming step S12. (b) of FIG. 6 is a diagram illustrating the separation layer forming step S12 using the ingot 11 whose front surface 11a is convex at the center, and (b) of FIG. 7 is a diagram illustrating the separation layer forming step S12 using the ingot 11 whose front surface 11a is concave at the center.

In the separation layer forming step S12, a separation layer is formed inside the ingot 11. More specifically, in the separation layer forming step S12, a separation layer is formed inside the ingot 11 by applying a laser beam with a focal point of the laser beam positioned at a predetermined depth position from the front surface 11a of the ingot 11. For example, in the separation layer forming step S12, as illustrated in FIG. 5, a process is repeated in which the ingot 11 is fed such that the focal point moves from one end to the other end of the ingot 11 along the X-axis direction to form modified regions and cracks along the X-axis direction, then the ingot 11 is moved by a predetermined amount in the Y-axis direction, and then the ingot 11 is fed such that the focal point moves from the other end to the one end of the ingot 11 along the X-axis direction to form modified regions and cracks along the X-axis direction. Accordingly, a separation layer is formed inside the ingot 11.

When the laser beam is applied to the ingot 11, which is convex at the center as illustrated in (a) of FIG. 6, or the ingot 11 which is concave at the center as illustrated in(a) of FIG. 7 while keeping the position in the Z-axis direction constant, that is, while maintaining a constant distance from the horizontal line, the amount of grinding required to form a substrate W of a uniform thickness increases, and the material loss increases.

Therefore, in the separation layer forming step S12, as illustrated in (b) of FIG. 6 and (b) of FIG. 7, the laser beam is applied such that the depth from the front surface 11a of the ingot 11 is constant, according to the front surface shape information. Accordingly, a distance from the front surface 11a of the substrate W to the separation layer is uniform.

### Separation Step

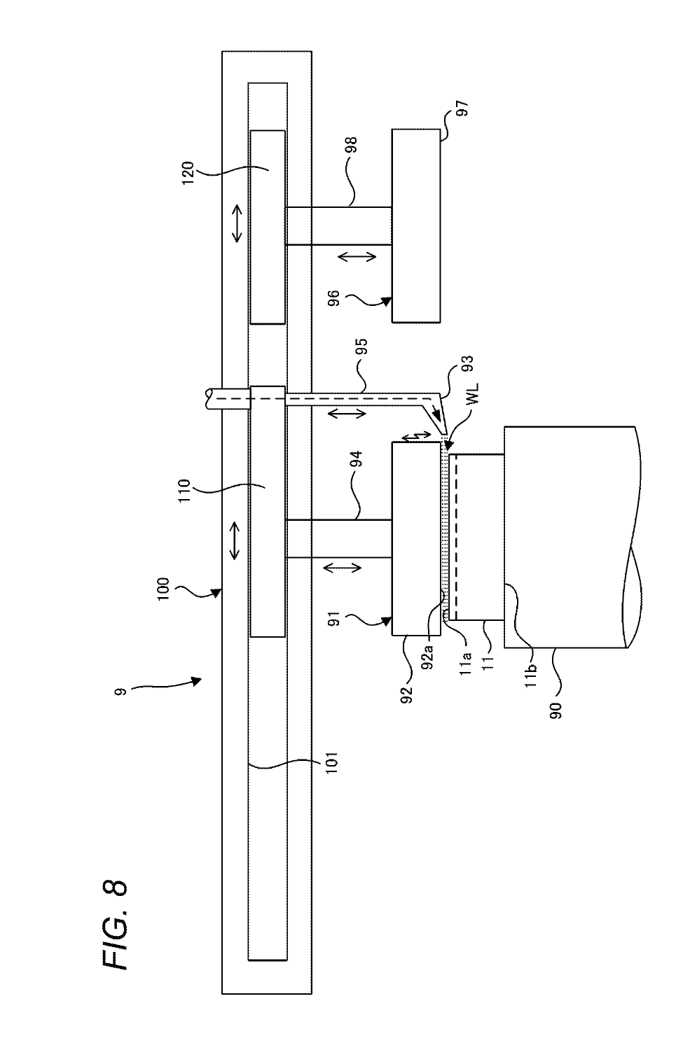

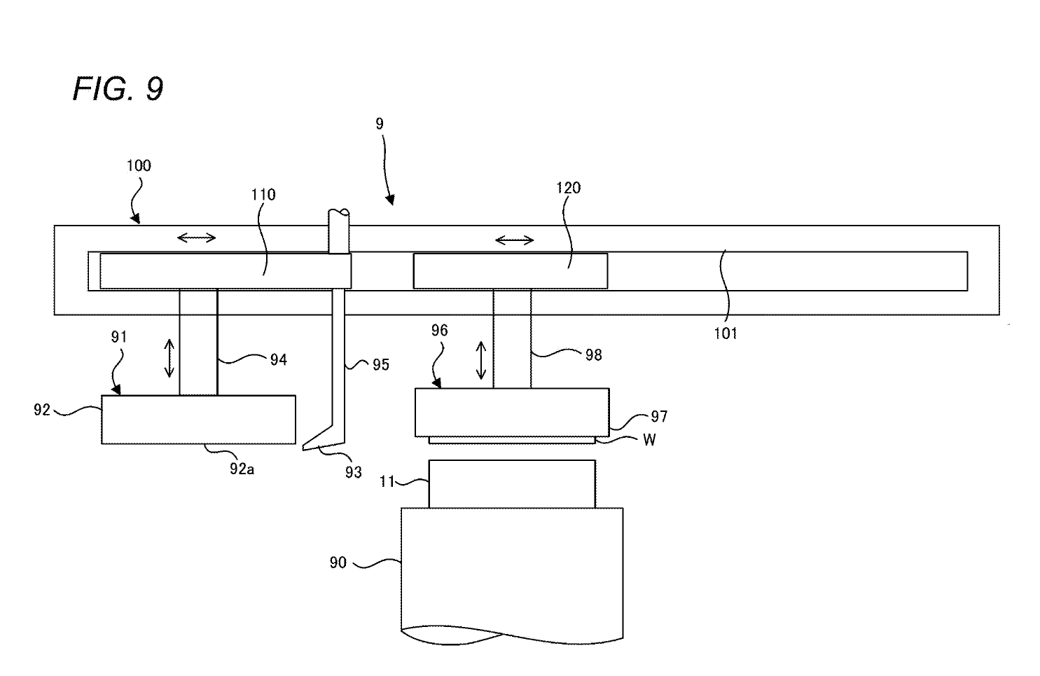

FIG. 8 is a diagram illustrating a state in which ultrasonic waves are applied to the ingot 11 in the separation step S13, and FIG. 9 is a diagram illustrating a state in which a substrate W is separated from the ingot 11 in the separation step S13.

The separation step S13 is a step of separating the substrate W from the ingot 11 along the separation layer formed in the separation layer forming step S12 by a separation device 9. The separation device 9 includes a cylindrical holding table 90 that holds the ingot 11 with the front surface 11a of the ingot 11 facing upward, an ultrasonic oscillation unit 91 that applies ultrasonic waves to the ingot 11, a separation unit 96 that separates the substrate W from the ingot 11, and a moving mechanism 100 that moves the ultrasonic oscillation unit 91 and the separation unit 96 in a horizontal direction.

For example, the holding table 90 holds the ingot 11 via an epoxy resin-based adhesive, or holds the ingot 11 under suction by a suction force generated by a suction source (not illustrated). The holding table 90 is rotatable about an axis that passes through a radial center and extends in a vertical direction.

A rectangular opening 101 extending in the horizontal direction is formed in the moving mechanism 100, and a moving piece 110 supporting the ultrasonic oscillation unit 91 and a moving piece 120 supporting the separation unit 96 are movable along the opening 101. Although not illustrated, the moving mechanism 100 includes a ball screw coupled to the moving pieces 110 and 120, a motor that rotates the ball screw, and the like.

The ultrasonic oscillation unit 91 includes an ultrasonic transducer 92 that applies ultrasonic waves to the ingot 11, a liquid supply nozzle 93 that supplies a liquid (for example, pure water) between the front surface 11a of the ingot 11 and the ultrasonic transducer 92, a transducer lifting mechanism 94 that adjusts a vertical position of the ultrasonic transducer 92, and a nozzle lifting mechanism 95 that adjusts a vertical position of the liquid supply nozzle 93. The transducer lifting mechanism 94 and the nozzle lifting mechanism 95 are implemented by air cylinders, ball screws, motors, and the like.

The ultrasonic transducer 92 has an end surface 92a facing the front surface 11a of the ingot 11. The ultrasonic transducer 92 is positioned by the transducer lifting mechanism 94 at a position where a small gap is provided between the end surface 92a and the front surface 11a of the ingot 11.

While ultrasonic waves are being applied to the ingot 11, the liquid supply nozzle 93 continuously supplies a liquid to the gap between the end surface 92a of the ultrasonic transducer 92 and the front surface 11a of the ingot 11 to form a liquid layer WL. The ultrasonic waves emitted from the ultrasonic transducer 92 are transmitted to the ingot 11 via the liquid layer WL, and extend the cracks of the separation layer formed in the ingot 11. Accordingly, the strength of the separation layer decreases.

The separation unit 96 includes a suction pad 97 that holds the substrate W separated from the ingot 11 under suction, and a pad lifting mechanism 98 that adjusts a vertical position of the suction pad 97. The pad lifting mechanism 98 is implemented by an air cylinder, a ball screw, a motor, and the like.

After ultrasonic waves are applied to the entire front surface 11a of the ingot 11, the moving pieces 110 and 120 move, and the suction pad 97 moves to a position facing the ingot 11 held on the holding table 90. Then, the separation unit 96 causes the suction pad 97 to suction the front surface 11a of the ingot 11 and moves the suction pad 97 upward, thereby separating, as the substrate W, a plate-shaped object including the front surface 11a of the ingot 11 along the separation layer of the ingot 11.

### Warpage Shape Information Acquisition Step

A front surface Wa of the separated substrate W is originally the front surface 11a of the ingot 11 and has been ground in the ingot grinding step S19 to be described later. On the other hand, a back surface Wb of the substrate W is a separated surface. That is, the processing state of the substrate W is different between the front surface Wa and the back surface Wb, and the Twyman effect occurs in the substrate W due to this difference in the processing state of both surfaces. The Twyman effect is a phenomenon in which, when there is a difference in residual stress on both surfaces of the substrate W, a force acts to compensate for the difference in the residual stress of both surfaces, and thus warpage occurs in the substrate W.

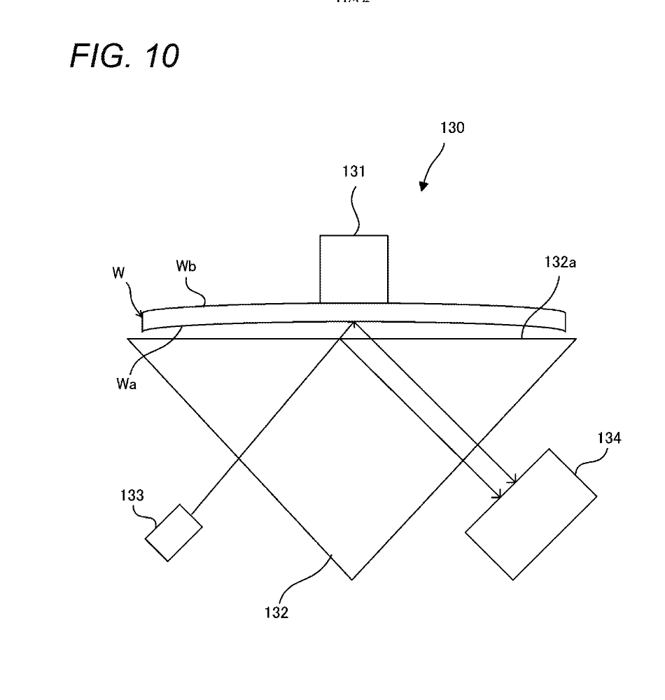

In the warpage shape information acquisition step S14, a warpage measurement device 130 measures a warpage shape of the substrate W separated from the ingot 11. FIG. 10 is a diagram illustrating the warpage shape information acquisition step S14, and is a top view of the warpage measurement device 130. The warpage measurement device 130 includes a holder 131 that holds the substrate W upright by laterally holding the vicinity of a center position of the back surface Wb of the substrate W, a prism 132 disposed so as to face the front surface Wa of the substrate W, a distance-measuring light source 133 that applies a distance-measuring laser beam, and a camera 134 that detects a phase difference between reference light reflected by a front surface 132a of the prism 132 and test light reflected by the front surface Wa of the substrate W.

The warpage measurement device 130 splits the light emitted from the distance-measuring light source 133 into two or more beams, overlaps the beams again after passing through separate optical paths, captures interference fringes generated by the difference in optical path lengths using the camera 134, and analyzes the interference fringes to determine the warpage shape of the substrate W. Such interferometers in which light is obliquely incident on the object (target) are collectively referred to as oblique incidence interferometers, and when such oblique incidence interferometers are used, the shape can be measured with high accuracy. However, the measurement of the warpage shape is not limited to the oblique incidence interference method, and other methods such as a Fizeau interference method and fringe scanning can also be used.

### Substrate Planarization Step

Next, the substrate planarization step S15 is a step of planarizing the substrate W separated from the ingot 11. The substrate planarization step S15 includes the substrate grinding step S16 of grinding the separation layer of the substrate W separated from the ingot 11, and a substrate polishing step S17 of further grinding and/or polishing the substrate W after grinding.

### Substrate Grinding Step

First, the substrate grinding step S16 will be described. The substrate grinding step S16 is a step of grinding the separated surface of the substrate W separated in the separation step S13 by a substrate grinding device 60A. Here, the substrate grinding device 60A will be described.

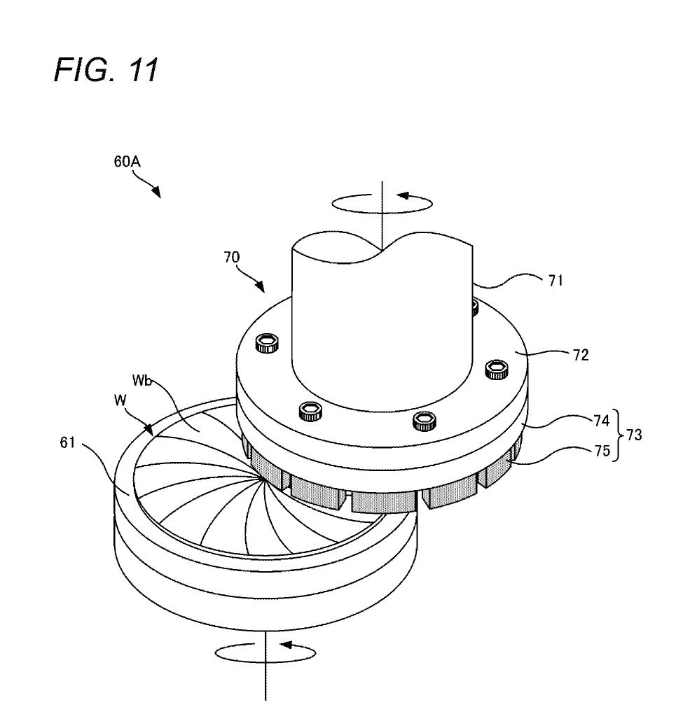

FIG. 11 is a perspective view illustrating the substrate grinding step S16. The substrate grinding device 60A includes a holding table 61 that holds the substrate W to be ground under suction, and a grinding unit 70 that grinds the substrate W held under suction on the holding table 61. The holding table 61 is coupled to a rotation drive source (not illustrated) such as a motor, and is rotatable about a rotation axis perpendicular to a holding surface by operating the rotation drive source.

The grinding unit 70 provided above the holding table 61 includes a spindle 71 substantially perpendicular to the holding table 61 and a rotation drive source (not illustrated) such as a motor for rotating the spindle 71. A disk-shaped wheel mount 72 is fixed to a lower end of the spindle 71, and a grinding wheel 73 is fixed to a lower end of the wheel mount 72.

The grinding wheel 73 includes a circular base 74 made of a metal material such as stainless steel or aluminum, and a plurality of grindstones 75 annularly disposed on a lower surface of the base 74. The grindstones 75 contain a binder made of ceramics, resin, a metal material, and the like, and numerous abrasive grains such as diamond dispersed and fixed in the binder.

In the substrate grinding device 60A configured as described above, in the substrate grinding step S16, a positional relation between the holding table 61 and the grinding unit 70 is adjusted such that a center of the substrate W held by the holding table 61 coincides with tracks of the grindstones. Then, while rotating the holding table 61 and the grinding wheel 73, the grinding wheel 73 is lowered along a feeding direction (vertical direction) parallel to a rotation axis of the spindle 71, and lower surfaces of the grindstones 75 are brought into contact with the substrate W held under suction on the holding table 61, thereby starting grinding of the substrate W. As the grinding of the substrate W proceeds, the separation layer is removed and the substrate W can be planarized.

### Substrate Polishing Step

Next, the substrate polishing step S17 will be described. The substrate polishing step S17 is a step of further grinding the separated surface of the substrate W ground in the substrate grinding step S16 by a polishing device 180. Here, the polishing device 180 will be described.

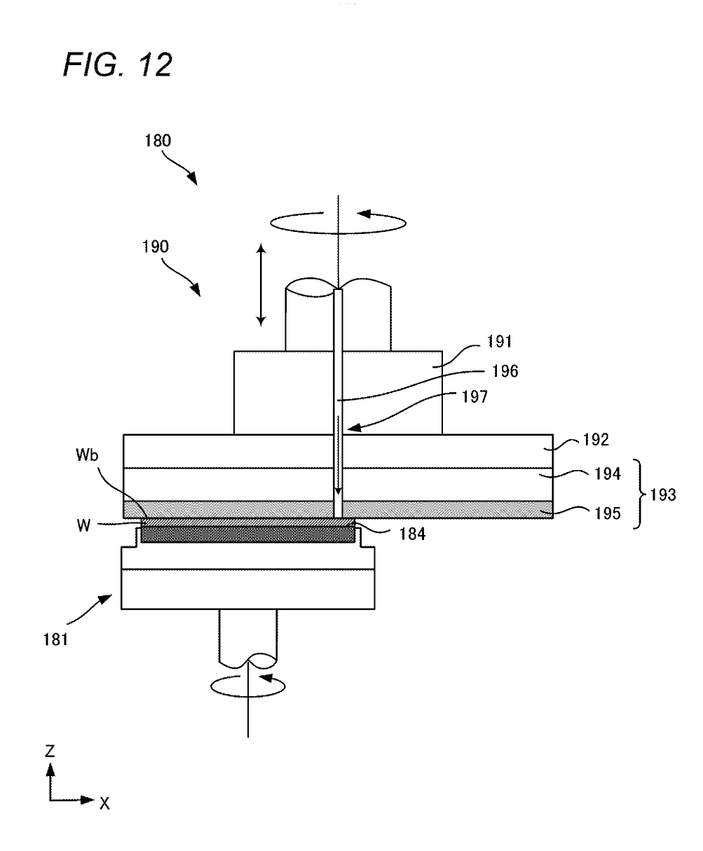

FIG. 12 is a diagram illustrating the substrate polishing step S17. The polishing device 180 includes a holding table 181 that holds the substrate W under suction, and a polishing unit 190 that polishes the substrate W held on a holding surface 184 of the holding table 181. The holding table 181 is coupled to a rotation drive source (not illustrated) such as a motor, and is rotatable about a rotation axis perpendicular to the holding surface 184 by operating the rotation drive source.

The polishing unit 190 provided above the holding table 181 includes a spindle 191 substantially perpendicular to the holding table 181 and a rotation drive source (not illustrated) such as a motor for rotating the spindle 191. A disk-shaped wheel mount 192 is fixed to a lower end of the spindle 191, and a polishing wheel 193 is fixed to a lower end of the wheel mount 192.

The polishing wheel 193 includes a disk-shaped platen 194 made of a hard resin, and a disk-shaped polishing pad 195 fixed to a lower surface of the platen 194.

The polishing pad 195 is made of, for example, rigid polyurethane foam, and may have a nonwoven fabric instead of rigid polyurethane foam. When the substrate W is polished by the polishing pad 195, the substrate W is polished using a slurry containing free abrasive grains.

The polishing wheel 193 is disposed concentrically with the spindle 191 and the wheel mount 192. A through hole 196 penetrating the polishing pad 195, the platen 194, the wheel mount 192, and the spindle 191 is formed in a central portion of the polishing wheel 193 in a radial direction. A slurry supply source (not illustrated) is coupled to an upper end portion of the through hole 196. The through hole 196 functions as a slurry supply path 197 for supplying slurry to the substrate W and the polishing pad 195 when the substrate W is polished by the polishing pad 195.

In the polishing device 180 configured as described above, in the substrate polishing step S17, the substrate W is held under suction by the holding table 181, and the holding table 181 is disposed below the polishing wheel 193. Then, the spindle 191 and the holding table 181 are rotated at different rotational speeds, and the polishing pad 195 is lowered while supplying slurry from the slurry supply path 197 to the back surface Wb (separated surface) of the substrate W and a lower surface of the polishing pad 195. Then, the polishing pad 195 is pressed against the substrate W at a predetermined pressure to press the lower surface of the polishing pad 195 against the back surface Wb of the substrate W. In this way, the back surface Wb (separated surface) of the substrate W is polished, and the substrate W is polished to a mirror finish. The front surface Wa of the substrate W may also be subjected to the same processing as in the substrate polishing step S17.

### Ingot Grinding Step

Next, the ingot grinding step S19 will be described. The ingot grinding step S19 is a step of planarizing, by an ingot grinding device 60B, the separated surface of the ingot 11 from which the substrate W is separated in the separation step S13. Here, since the ingot grinding device 60B has substantially the same configuration as the substrate grinding device 60A, the same reference numerals are used and the description thereof will be omitted.

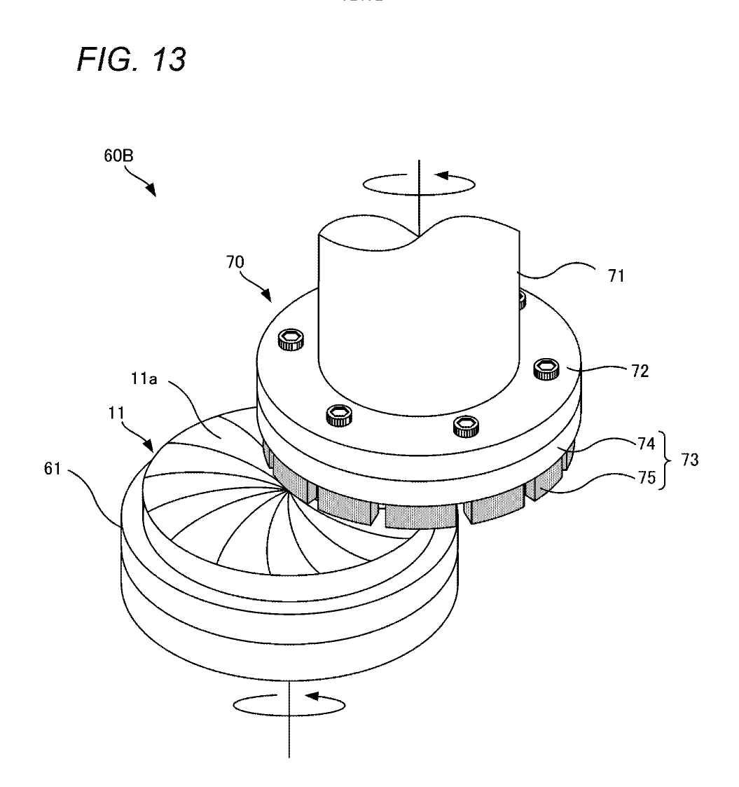

FIG. 13 is a perspective view illustrating the ingot grinding step S19. In the ingot grinding step S19, in the ingot grinding device 60B, a positional relation between the holding table 61 and the grinding unit 70 is adjusted such that the center of the ingot 11 held by the holding table 61 coincides with tracks of the grindstones. Then, while rotating the holding table 61 and the grinding wheel 73, the grinding wheel 73 is lowered along a feeding direction (vertical direction) parallel to a rotation axis of the spindle 71, and lower surfaces of the grindstones 75 are brought into contact with the ingot 11 held under suction on the holding table 61, thereby starting grinding of the ingot 11. As the grinding of the ingot 11 proceeds, the separation layer is removed.

Here, in the ingot grinding step S19, the separated surface of the ingot 11 after the substrate W is separated is ground based on the warpage shape information acquired in the warpage shape information acquisition step S14. If the substrate W after separation is warped and becomes convex upward or downward, for example, there is a risk that the substrate W cannot be suctioned during transport from the separation device 9 used in the separation step S13 to the substrate grinding device 60A used in the substrate grinding step S16.

Therefore, by grinding the front surface 11a of the ingot 11 to adjust the shape of the front surface 11a (separated surface) so as to reduce the warpage of the separated substrate W, the warpage of the substrate W after separation can be reduced, and transport failures of the substrate W can be prevented. For example, if the separated substrate W is warped and becomes convex toward the front surface Wa by a predetermined value or more, grinding is performed such that a central portion of an ingot is thinner than an outer edge portion (the height of the ingot 11 is decreased). On the other hand, if the substrate W after separation is warped and becomes convex toward the back surface Wb (separated surface) by a predetermined value or more, grinding is performed such that a central portion of an ingot is thicker than an outer edge portion (the height of the ingot 11 is increased).

Such adjustment of the amount of grinding is achieved by adjusting the inclination of the holding table 61 holding the ingot 11, adjusting the inclination of the grinding wheel 73, or adjusting the inclination of both the holding table 61 and the grinding wheel 73.

As described above, the front surface shape information acquisition step S11, the separation layer forming step S12, the separation step S13, the warpage shape information acquisition step S14, the substrate planarization step S15, and the ingot grinding step S19 are repeatedly performed, and a plurality of substrates W are produced from the ingot 11. According to the present embodiment, the thickness of the substrate W can be made uniform by accurately changing the focal point according to the front surface shape information. Accordingly, the material loss can be reduced, and the substrate planarization step S15 can be shortened.

By adjusting the shape of the front surface 11a (separated surface) of the ingot 11 based on the warpage shape information of the substrate W, the warpage of the substrate W to be separated next can be reduced. In the above embodiment, by performing the warpage shape information acquisition step S14 after the separation step S13 and before the substrate planarization step S15, for example, it is possible to reduce transport failures such as the inability to suction the substrate W during transport from the separation device 9 used in the separation step S13 to the substrate grinding device 60A used in the substrate grinding step S16.

In the above embodiment, the front surface shape information of the front surface 11a of the ingot 11 is measured in the front surface shape information acquisition step S11, and in the separation layer forming step S12, a laser beam is applied according to the front surface shape information such that a depth from the front surface 11a of the ingot 11 is constant, but the present disclosure is not limited thereto. That is, regardless of the front surface shape of the front surface 11a of the ingot 11, in the separation layer forming step S12, a laser beam may be applied such that a focal point of the laser beam is at a predetermined position (absolute position) deeper than the front surface 11a. In this case, it is not necessary to measure the front surface shape information in the front surface shape information acquisition step S11, and thus the production process can be simplified.

The warpage of the substrate W is not limited to the warpage caused by the difference in the processing state between the front surface Wa and the back surface Wb, and includes warpage caused by the difference in the crystal structure of the substrate W. Therefore, the warpage shape information acquisition step S14 may be performed after the substrate planarization step S15 in order to reduce the warpage caused by the difference in the crystal structure.

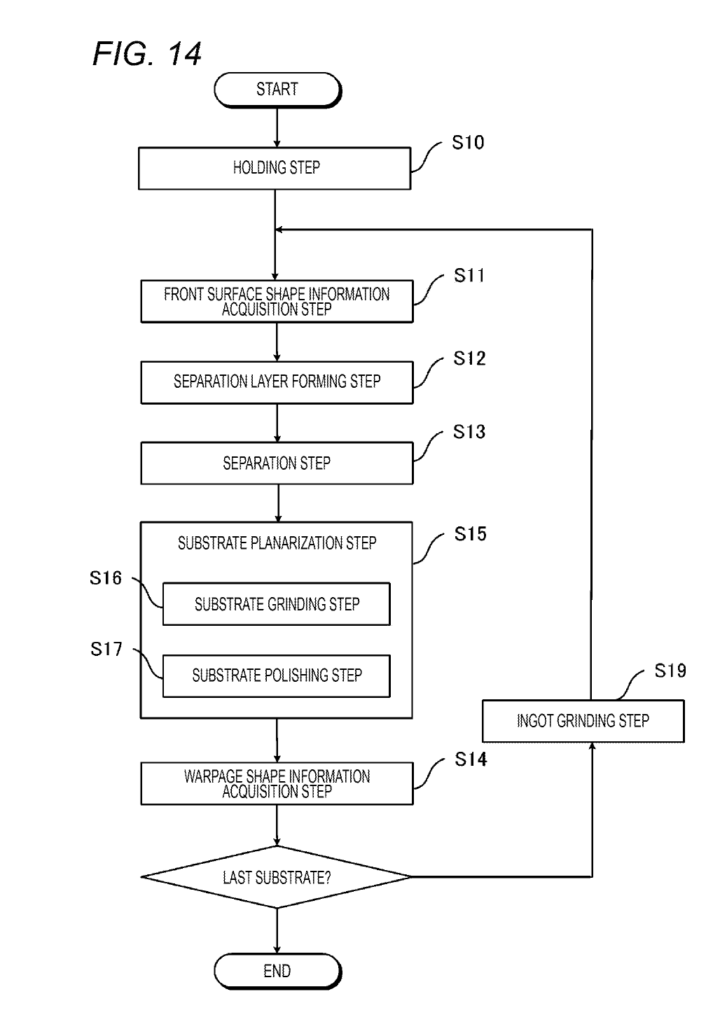

FIG. 14 is a flowchart of a modification of the method for producing a substrate W.

In the modification of the method for producing a substrate W illustrated in FIG. 14, a plurality of substrates W are generated from one ingot 11 held in the holding step S10, the front surface shape information acquisition step S11, the separation layer forming step S12, the separation step S13, the substrate planarization step S15, the warpage shape information acquisition step S14, and the substrate grinding step S16 are repeated until the last one substrate W is generated, and the processing is ended when the last one substrate W is generated. Since each step is the same as that of the above embodiment, the description thereof will be omitted.

In the present modification, by adjusting the shape of the front surface 11a (separated surface) of the ingot 11 according to the warpage of the substrate W remaining after the substrate planarization step S15, the warpage due to the difference in the crystal structure of the next substrate W can be reduced, and the quality of the substrate W can be improved.

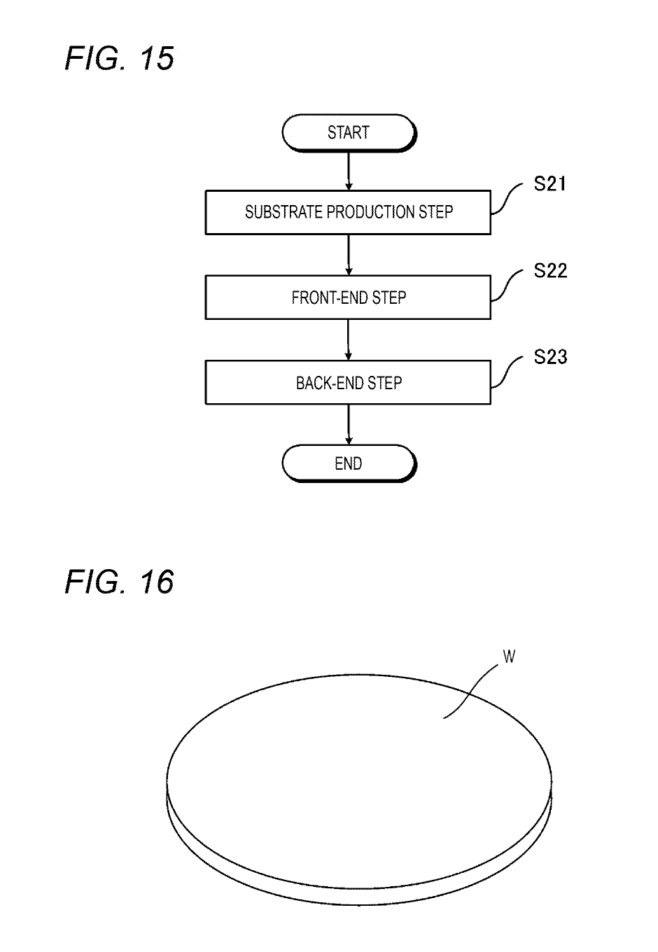

Next, a chip production method will be described. FIG. 15 is a flowchart of an embodiment of the chip production method.

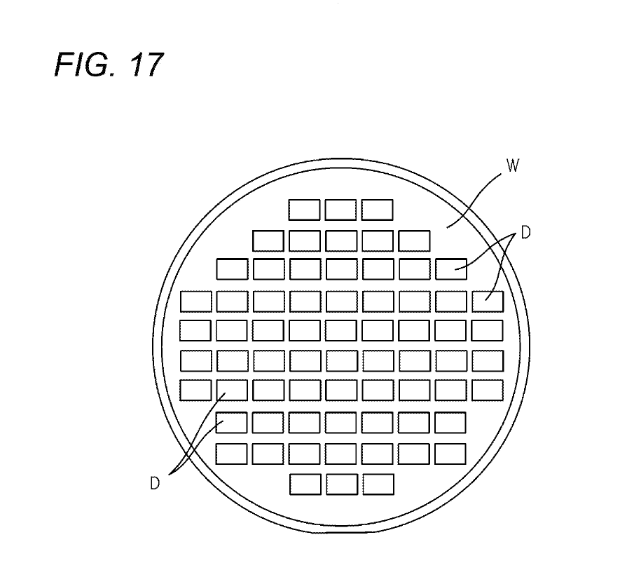

As illustrated in FIG. 15, the chip production method of the present embodiment includes a substrate production step S21, a front-end step S22, and a back-end step S23. The substrate production step S21 is a step of producing a substrate W by the method for producing a substrate W described above. FIG. 16 is a diagram illustrating the substrate W produced in the substrate production step S21. The front-end step S22 is a step of forming a circuit on the substrate W and producing a plurality of semiconductor devices D on the substrate W. FIG. 17 is a diagram illustrating a substrate W on which a plurality of semiconductor devices D are formed. The back-end step S23 is a step of assembling a semiconductor chip, in which, after the substrate W on which a plurality of semiconductor devices are formed is cut, wiring and resin encapsulation are performed to produce a semiconductor chip.

Although the embodiment of the present disclosure has been described above with reference to the accompanying drawings, it is needless to say that the present disclosure is not limited to this embodiment. It is obvious that those skilled in the art may come up with various changes or modifications within the scope of the claims, and it is understood that these naturally fall within the technical scope of the present disclosure. In addition, components in the embodiment described above may be freely combined without departing from the gist of the disclosure.

For example, the substrate production method of the embodiment described above has been described by taking the case where the workpiece is the ingot 11 as an example, but the present disclosure is not limited thereto, and the workpiece may be a substrate, for example. That is, one substrate may be further divided into a plurality of substrates by performing the substrate production method of the embodiment described above on the one substrate.

The present specification describes at least the following matters. Corresponding components and the like in the embodiment described above are shown in parentheses, but the present disclosure is not limited thereto.

(1) A substrate production method for producing, from a workpiece (ingot 11), a substrate (substrate W) thinner than the workpiece, the method including:

a separation layer forming step (separation layer forming step S12) of forming a separation layer inside the workpiece by applying a laser beam having a wavelength that transmits through the workpiece from a front surface (front surface 11a) of the workpiece, positioning a focal point of the laser beam at a position deeper than the front surface of the workpiece, and relatively feeding the workpiece and the focal point;

a separation step (separation step S13) of separating the substrate from the workpiece along the separation layer;

a warpage shape information acquisition step (warpage shape information acquisition step S14) of acquiring warpage shape information, which is shape information of warpage of the substrate; and

a workpiece grinding step (ingot grinding step S19) of grinding a separated surface of the workpiece by a grinding wheel (grinding wheel 73), in which

in the workpiece grinding step, the separated surface of the workpiece exposed after separation of the substrate is ground based on the warpage shape information acquired in the warpage shape information acquisition step.

According to (1), in the workpiece grinding step, since the separated surface of the workpiece exposed after separation of the substrate is ground based on the warpage shape information acquired in the warpage shape information acquisition step, the separated surface of the workpiece can be ground such that the warpage of the substrate to be separated next can be reduced. Accordingly, it is possible to reduce the warpage of the substrate separated from the workpiece, and it is possible to prevent transport failures such as the inability to suction the substrate. In addition, since the warpage of the substrate separated from the workpiece is reduced, the quality of the substrate can be improved.

(2) The substrate production method according to (1), further including:

a front surface shape information acquisition step (front surface shape information acquisition step S11) of acquiring front surface shape information, which is shape information of the front surface of the workpiece, before the separation layer forming step, in which

in the separation layer forming step, the laser beam is applied while adjusting a height of the focal point based on the front surface shape information acquired in the front surface shape information acquisition step.

According to (2), a thickness of the substrate to be separated can be adjusted.

(3) The substrate production method according to (2), in which

in the separation layer forming step, the laser beam is applied while controlling a depth from the front surface of the workpiece to the focal point at which the separation layer is formed to be constant.

According to (3), since the thickness of the substrate can be made uniform, the amount of grinding during substrate grinding can be reduced, and the material loss can be reduced.

(4) The substrate production method according to (1) or (2), further including:

a substrate planarization step (substrate planarization step S15) of grinding or polishing the separated surface of the substrate after the separation step.

According to (4), it is possible to planarize the separated surface of the substrate.

(5) The substrate production method according to (4), in which

the warpage shape information acquisition step is a step of acquiring the warpage shape information of the substrate after the separation step and before the substrate planarization step.

According to (5), it is possible to acquire a warpage shape caused by a difference in the front surface state between the surface on one side and the surface on the other side of the substrate.

(6) The substrate production method according to (4), in which

the warpage shape information acquisition step is a step of acquiring the warpage shape information of the substrate after the substrate planarization step.

According to (6), it is possible to acquire a warpage shape caused by a difference in the crystal structure of the substrate.

(7) The substrate production method according to any one of (1) to (6), in which

in the workpiece grinding step, a shape of the separated surface of the workpiece is adjusted by adjusting an inclination of the grinding wheel or a holder (holding table 61) that holds the workpiece.

According to (7), the shape of the separated surface of the workpiece can be adjusted while grinding.

(8) A chip production method including:

a substrate production step (substrate production step S21) of producing a substrate by the substrate production method according to any one of (1) to (7);

a front-end step (front-end step S22) of producing a plurality of semiconductor devices on the substrate; and

a back-end step (back-end step S23) of producing a semiconductor chip by cutting the substrate on which the plurality of semiconductor devices are formed.

According to (8), the warpage of the substrate separated from the workpiece can be reduced, and the quality of the substrate can be improved. Thereby, the accuracy of the chip can be improved.

### REFERENCE SIGNS LIST

11 ingot (workpiece)

11a front surface

61 holding table (holder)

73 grinding wheel

S11 front surface shape information acquisition step

S12 separation layer forming step

S13 separation step

S15 substrate planarization step

S19 ingot grinding step (workpiece grinding step)

S21 substrate production step

S22 front-end step

S23 back-end step

W substrate

What is claimed is:

1. A substrate production method for producing, from a workpiece, a substrate thinner than the workpiece, the method comprising:
forming a separation layer inside the workpiece by applying a laser beam having a wavelength that transmits through the workpiece from a front surface of the workpiece, positioning a focal point of the laser beam at a position deeper than the front surface of the workpiece, and relatively feeding the workpiece and the focal point;
separating the substrate from the workpiece along the separation layer;
acquiring warpage shape information, which is shape information of warpage of the substrate; and
grinding a separated surface of the workpiece by a grinding wheel, wherein
in the grinding, the separated surface of the workpiece exposed after separation of the substrate is ground based on the acquired warpage shape information.

2. The substrate production method according to claim 1, further comprising:
acquiring front surface shape information, which is shape information of the front surface of the workpiece, before the forming of the separation layer, wherein
in the forming of the separation layer, the laser beam is applied while adjusting a height of the focal point based on the acquired front surface shape information.

3. The substrate production method according to claim 2, wherein
in the forming of the separation layer, the laser beam is applied while controlling a depth from the front surface of the workpiece to the focal point at which the separation layer is formed to be constant.

4. The substrate production method according to claim 1, further comprising:
grinding or polishing the separated surface of the substrate after the separating of the substrate.

5. The substrate production method according to claim 2, further comprising:
grinding or polishing the separated surface of the substrate after the separating of the substrate.

6. The substrate production method according to claim 4, wherein
the acquiring of warpage shape information is acquiring the warpage shape information of the substrate after the separating of the substrate and before the grinding or polishing of the separated surface of the substrate.

7. The substrate production method according to claim 5, wherein
the acquiring of warpage shape information is acquiring the warpage shape information of the substrate after the separating of the substrate and before the grinding or polishing of the separated surface of the substrate.

8. The substrate production method according to claim 4, wherein
the acquiring of warpage shape information is acquiring the warpage shape information of the substrate after the grinding or polishing of the separated surface of the substrate.

9. The substrate production method according to claim 5, wherein
the acquiring of warpage shape information is acquiring the warpage shape information of the substrate after the grinding or polishing of the separated surface of the substrate.

10. The substrate production method according to claim 1, wherein
in the grinding of the separated surface of the workpiece, a shape of the separated surface of the workpiece is adjusted by adjusting an inclination of the grinding wheel or a holder that holds the workpiece.

11. The substrate production method according to claim 2, wherein
in the grinding of the separated surface of the workpiece, a shape of the separated surface of the workpiece is adjusted by adjusting an inclination of the grinding wheel or a holder that holds the workpiece.

12. A chip production method comprising:
producing a substrate by the substrate production method according to claim 1;
producing a plurality of semiconductor devices on the substrate; and
producing a semiconductor chip by cutting the substrate on which the plurality of semiconductor devices are formed.

13. A chip production method comprising:
producing a substrate by the substrate production method according to claim 2;
producing a plurality of semiconductor devices on the substrate; and
producing a semiconductor chip by cutting the substrate on which the plurality of semiconductor devices are formed.
